(19) United States
(12) Patent Application Publication
(10) Pub. No.: US 2024/0355885 A1
(43) Pub. Date: Oct. 24, 2024

(54) SILICON CARBIDE SEMICONDUCTOR DEVICE AND METHOD OF MANUFACTURING SILICON CARBIDE SEMICONDUCTOR DEVICE

(71) Applicant: FUJI ELECTRIC CO., LTD., Kawasaki-shi (JP)

(72) Inventors: Takeshi TAWARA, Tsukuba-city (JP); Shinsuke HARADA, Tsukuba-city (JP); Masashi KATO, Nagoya-shi (JP); Takuya FUKUI, Nagoya-shi (JP)

(73) Assignee: FUJI ELECTRIC CO., LTD., Kawasaki-shi (JP)

(21) Appl. No.: 18/760,097

(22) Filed: Jul. 1, 2024

Related U.S. Application Data
(63) Continuation of application No. PCT/JP2023/006093, filed on Feb. 20, 2023.

(30) Foreign Application Priority Data
Feb. 21, 2022 (JP) 2022-025142

(51) Int. Cl. H01L 29/10; H01L 21/04; H01L 29/16; H01L 29/66; H01L 29/78

(52) U.S. Cl. CPC H01L 29/1083; H01L 21/046; H01L 29/1608; H01L 29/66068; H01L 29/7813

(57) ABSTRACT

A silicon carbide semiconductor device has a silicon carbide semiconductor substrate of a first conductivity type, a first semiconductor layer of the first conductivity type and having a doping concentration lower than a doping concentration of the silicon carbide semiconductor substrate, a second semiconductor layer of a second conductivity type, first semiconductor regions of the first conductivity type, trenches, first base regions, second base regions of the second conductivity type, and a co-doped region doped with aluminum and nitrogen. The co-doped region is provided in the first semiconductor layer, including regions between the first base regions and the second base regions and a layer that is closer to the silicon carbide semiconductor substrate than are the first base regions and the second base regions. The co-doped region has a carrier lifetime of not more than 0.01 μs.

### CROSS REFERENCE TO RELATED APPLICATIONS

This is a continuation application of International Application PCT/JP2023/006093 filed on Feb. 20, 2023 which claims priority from a Japanese Patent Application No. 2022-025142 filed on Feb. 21, 2022, the contents of which are incorporated herein by reference.

### BACKGROUND OF THE INVENTION

### 1. Field of the Invention

Embodiments of the invention relate to a silicon carbide semiconductor device and a method of manufacturing a silicon carbide semiconductor device.

### 2. Description of the Related Art

Conventionally, in a power semiconductor device, a vertical metal-oxide-semiconductor field-effect transistor (MOSFET) having a trench structure is fabricated (manufactured) to reduce on-resistance of the device. In a vertical MOSFET, the cell density per unit area may be increased to a greater extent with a trench structure in which a channel is formed orthogonal to the substrate surface as compared to a planar structure in which a channel is formed parallel to the substrate surface, whereby the current density per unit area may be increased, thereby making the trench structure advantageous in terms of cost.

FIG. 25 is a cross-sectional view depicting a structure of an active region of a conventional silicon carbide semiconductor device. FIG. 26 is a cross-sectional view depicting a structure of a termination structure region of the conventional silicon carbide semiconductor device. FIG. 27 is a plan view depicting the structure of the conventional silicon carbide semiconductor device along cutting line B-B′ in FIG. 25. FIG. 28 is a plan view depicting the structure of the conventional silicon carbide semiconductor device along cutting line C-C′ in FIG. 25.

FIGS. 25, 26, 27, and 28 depict a trench-type MOSFET 150 as the conventional silicon carbide semiconductor device. As depicted in FIG. 25, the trench-type MOSFET 150 has a MOS gate of a general trench gate structure in a stacked semiconductor substrate (hereinafter, stacked silicon carbide substrate) containing silicon carbide, the MOS gate being provided at a front surface (surface having a later described p-type base layer 103) of the stacked silicon carbide substrate. The stacked silicon carbide substrate (semiconductor chip) is formed by sequentially growing an n⁻-type drift layer 102, an n-type high-concentration region 106 constituting a current spreading region and silicon carbide layers constituting the p-type base layer 103 by epitaxy, on an n⁺-type support substrate (hereinafter, n⁺-type silicon carbide substrate) 101 containing silicon carbide.

At a front side (side having the n⁻-type drift layer 102) of the n⁺-type silicon carbide substrate 101, a MOS gate structure formed by the p-type base layer 103, n⁺-type source regions 107, trenches 116, gate insulating films 109, and gate electrodes 110 is provided. Further, reference numerals 108, 111, 112, and 114 are, respectively, p⁺⁺-type contact regions, an interlayer insulating film, a source electrode, and a source electrode pad.

At a back surface of the n⁺-type silicon carbide substrate 101, a back electrode 113 constituting a drain electrode is provided.

Between the trenches 116, first p⁺-type base regions 104 are selectively provided in the n-type high-concentration region 106. The first p⁺-type base regions 104 are provided at a depth so as to not reach the n⁻-type drift layer 102. Each of the first p⁺-type base regions 104 is configured by a first p⁺-type region 104a of a same thickness as a thickness of a second p⁺-type base region 105 depicted below and a second p⁺-type region 104b provided at the surface of the first p⁺-type region 104a. Further, in the n-type high-concentration region 106, each second p⁺-type base region 105 is selectively provided so as to underlie an entire area of a bottom of a corresponding one of the trenches 116. Further, as depicted in FIG. 27, the first p⁺-type regions 104a and the second p⁺-type base regions 105 are connected to one another in a lattice-like pattern and the n-type high-concentration region 106 is selectively formed.

Further, as depicted in FIG. 26, the trench-type MOSFET 150 has an active region 130 in which a device structure is formed, current flowing through the active region 130 during an on-state; a termination structure region 132 surrounding a periphery of the active region 130 and sustaining a breakdown voltage; and a connecting region 131 between the active region 130 and the termination structure region 132.

In the termination structure region 132, the p-type base layer 103 and the n-type high-concentration region 106 are removed, the n⁻-type silicon carbide drift layer 102 is exposed, and on the n⁻-type silicon carbide drift layer 102, a voltage withstand structure such as a junction termination extension (JTE) is provided.

The JTE structure has p-type regions disposed in descending order of doping concentration in a direction from a center (center of the n⁺-type silicon carbide substrate 101) to a substrate end (end of the n⁺-type silicon carbide substrate 101). Further, the p-type regions (in FIG. 26, a JTE1 region 133, a JTE2 region 134) of different doping concentrations are disposed in a substantially rectangular shape surrounding the periphery of the active region 130 in a plan view of the device. Outside the JTE structure, a high-concentration n-type region 24 constituting a channel stopper is disposed. At surfaces of the JTE structure and the n-type region 24, the interlayer insulating film 111 is provided and at a surface of the trench-type MOSFET 150, a protective film 125 containing a polyimide or the like is provided.

Here, FIG. 29 is a graph showing a dopant depth profile of the conventional silicon carbide semiconductor device. In FIG. 29, a horizontal axis indicates depth in a direction indicated by arrow A in FIG. 25 while a vertical axis indicates concentrations of aluminum (Al) and nitrogen (N). Here, a JFET1 region 121 is a portion of the n-type high-concentration region 106 between a sidewall of any one of the trenches 116 and an adjacent one of the second p⁺-type regions 104b while a JFET2 region 122 is a portion of the n-type high-concentration region 106 between any one of the second p⁺-type base regions 105 and an adjacent one of the first p⁺-type regions 104a (refer to FIG. 25). In FIG. 29, the vertical axis is in logarithmic scale and thus, while the N concentration has a finite value in the p-type base layer 103, N is not intentionally added, which means that the N concentration is lower than a detection limit. Similarly, in the n-type high-concentration region 106 and the n⁻-type silicon carbide drift layer 102, Al is not intentionally added, which means that the Al concentration is lower than the detection limit of secondary ion mass spectrometry (5×10¹³/cm³).

A silicon carbide semiconductor device containing aluminum as an impurity in the first base region provided between the trenches is commonly known (for example, refer to Japanese Laid-Open Patent Publication No. 2020-155438). Further, a silicon semiconductor device containing aluminum in a p-type bottom region in contact with the bottom of a trench is commonly known (for example, refer to Japanese Laid-Open Patent Publication No. 2018-133442).

### SUMMARY OF THE INVENTION

According to an embodiment of the present invention, a silicon carbide semiconductor device includes: a silicon carbide semiconductor substrate of a first conductivity type, the silicon carbide semiconductor substrate having a first main surface and a second main surface opposite to each other; a first semiconductor layer of the first conductivity type, provided at the first main surface of the silicon carbide semiconductor substrate, the first semiconductor layer having a doping concentration lower than a doping concentration of the silicon carbide semiconductor substrate, the first semiconductor layer having a first surface and a second surface opposite to each other, the second surface facing the silicon carbide semiconductor substrate; a second semiconductor layer of a second conductivity type, provided at the first surface of the first semiconductor layer, the second semiconductor layer having a first surface and a second surface opposite to each other, the second surface facing the silicon carbide semiconductor substrate; a first semiconductor region of the first conductivity type, selectively provided in the second semiconductor layer, at the first surface of the second semiconductor layer; a trench penetrating through the second semiconductor layer and the first semiconductor region and reaching the first semiconductor layer; a first base region of the second conductivity type, provided at the first surface of the first semiconductor layer; a second base region of the second conductivity type, provided in the first semiconductor layer, at a position facing a bottom of the trench in a depth direction of the device; a gate insulating film provided in the trench; a gate electrode provided on the gate insulating film in the trench; an interlayer insulating film provided on the gate electrode; a first electrode in contact with the first semiconductor region and the second semiconductor layer; a second electrode provided at the second main surface of the silicon carbide semiconductor substrate; and a co-doped region provided in the first semiconductor layer, including a region between the first base region and second base region and a layer that is closer to the silicon carbide semiconductor substrate than are the first base region and the second base region, the co-doped region being doped with aluminum and nitrogen. The co-doped region has a carrier lifetime not more than 0.01 μs.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view of a structure of an active region a silicon carbide semiconductor device according to a first embodiment, along cutting line A-A′ in FIG. 3.

FIG. 2 is a cross-sectional view depicting the structure of a termination structure region of the silicon carbide semiconductor device according to the first embodiment.

FIG. 3 is a plan view of the structure of the silicon carbide semiconductor device according to the first embodiment, along cutting line B-B′ in FIG. 1.

FIG. 4 is a plan view of the structure of the silicon carbide semiconductor device according to the first embodiment, along cutting line C-C′ in FIG. 1.

FIG. 5 is a graph showing a dopant depth profile of the silicon carbide semiconductor device according to the first embodiment.

FIG. 6A is a graph showing, by comparison of a non-SJ-multiepi device in FIG. 7 and a semi-SJ device in FIG. 8 decreases in the lifetime due to Al ion-implantation in the silicon carbide semiconductor device.

FIG. 6B is a graph showing, by comparison of a non-SJ-multiepi device in FIG. 7 and a semi-SJ device in FIG. 8 decreases in the lifetime due to Al ion-implantation in the silicon carbide semiconductor device.

FIG. 7 is a cross-sectional view depicting a structure of multiepi of the non-SJ-multiepi, which is a trench MOS structure in which no superjunction structure is formed in the drift layer.

FIG. 8 is a cross-sectional view depicting, in addition to the structure in FIG. 7, a semi-SJ silicon carbide semiconductor device, which is a trench MOS structure in which Al ion-implantation is performed in portions of the drift layer.

FIG. 9 is a diagram depicting L1 line emission intensity of the silicon carbide semiconductor device in FIG. 7.

FIG. 10 is a diagram depicting L1 line emission intensity of the silicon carbide semiconductor device in FIG. 8.

FIG. 11 is a cross-sectional view schematically depicting a state of the silicon carbide semiconductor device according to the first embodiment during manufacture.

FIG. 12 is a cross-sectional view schematically depicting a state of the silicon carbide semiconductor device according to the first embodiment during manufacture.

FIG. 13 is a cross-sectional view schematically depicting a state of the silicon carbide semiconductor device according to the first embodiment during manufacture.

FIG. 14 is a cross-sectional view schematically depicting a state of the silicon carbide semiconductor device according to the first embodiment during manufacture.

FIG. 15 is a cross-sectional view schematically depicting a state of the silicon carbide semiconductor device according to the first embodiment during manufacture.

FIG. 16 is a cross-sectional view schematically depicting a state of the silicon carbide semiconductor device according to the first embodiment during manufacture.

FIG. 17 is a cross-sectional view schematically depicting a state of the silicon carbide semiconductor device according to the first embodiment during manufacture.

FIG. 18 is a cross-sectional view schematically depicting a state of the silicon carbide semiconductor device according to the first embodiment during manufacture.

FIG. 19 is a cross-sectional view schematically depicting a state of the silicon carbide semiconductor device according to the first embodiment during manufacture.

FIG. 20 is a cross-sectional view depicting a structure of an active region of a silicon carbide semiconductor device according to a second embodiment.

FIG. 21 is a cross-sectional view depicting a structure of a termination structure region of the silicon carbide semiconductor device according to the second embodiment.

FIG. 22 is a graph showing a dopant depth profile of the silicon carbide semiconductor device according to the second embodiment.

FIG. 23 is a cross-sectional view schematically depicting a state of the silicon carbide semiconductor device according to the second embodiment during manufacture.

FIG. 24A is a cross-sectional view schematically depicting a state of the silicon carbide semiconductor device according to the second embodiment during manufacture.

FIG. 24B is a cross-sectional view schematically depicting a state of the silicon carbide semiconductor device according to the second embodiment during manufacture.

FIG. 25 is a cross-sectional view depicting a structure of an active region of a conventional silicon carbide semiconductor device.

FIG. 26 is a cross-sectional view depicting a structure of a termination structure region of the conventional silicon carbide semiconductor device.

FIG. 27 is a plan view depicting the structure of the conventional silicon carbide semiconductor device along cutting line B-B′ in FIG. 25.

FIG. 28 is a plan view depicting the structure of the conventional silicon carbide semiconductor device along cutting line C-C′ in FIG. 25.

FIG. 29 is a graph showing a dopant depth profile of the conventional silicon carbide semiconductor device.

### DETAILED DESCRIPTION OF THE INVENTION

First, problems associated with the conventional techniques are discussed. Vertical MOSFETs like that described have an intrinsic parasitic pn diode formed between the p-type base layer 103 and the n⁻-type silicon carbide drift layer 102, as a body diode between a source and drain. Thus, a freewheeling diode (FWD) used in an inverter may be omitted, contributing to reductions in cost and size. However, when the parasitic pn diode turns on and conducts, holes are injected into the n⁻-type silicon carbide drift layer 102 from the p-type base layer 103 while electrons are injected from the n⁺-type silicon carbide substrate 101 side. A problem arises in that due to this injection of excess carriers into the n⁻-type silicon carbide drift layer 102, switching loss increases and stacking faults expand, whereby conduction degrades.

Embodiments of a silicon carbide semiconductor device and a method of manufacturing a silicon carbide semiconductor device according to the present invention are described in detail with reference to the accompanying drawings. In the present description and accompanying drawings, layers and regions prefixed with n or p mean that majority carriers are electrons or holes. Additionally, + or − appended to n or p means that the doping concentration is higher or lower, respectively, than layers and regions without + or −. Cases where symbols such as n's and p's that include + or − are the same indicate that concentrations are close and therefore, the concentrations are not necessarily equal. A lower case “n” and “p” are used as symbols of the conductivity type of a semiconductor. While nitrogen (N) and phosphorus (P) are discussed as doping elements, the elements are indicated in capital letters. In the description of the embodiments below and the accompanying drawings, main portions that are identical are given the same reference numerals and are not repeatedly described. Further, with consideration of variation in manufacturing, description indicating the same or equal may be within 5%.

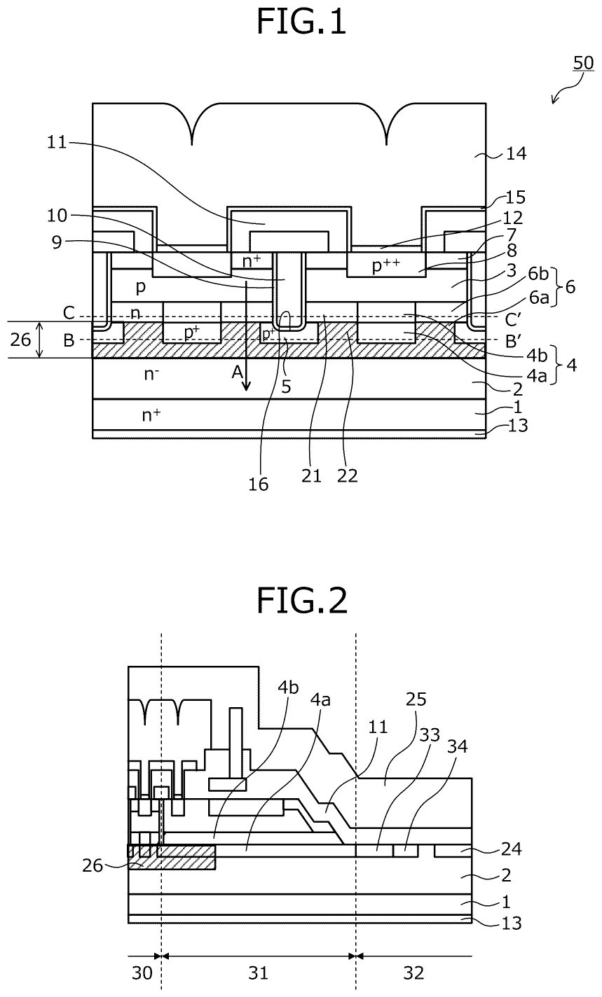

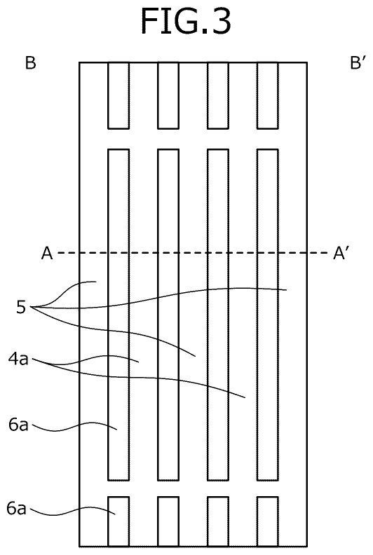

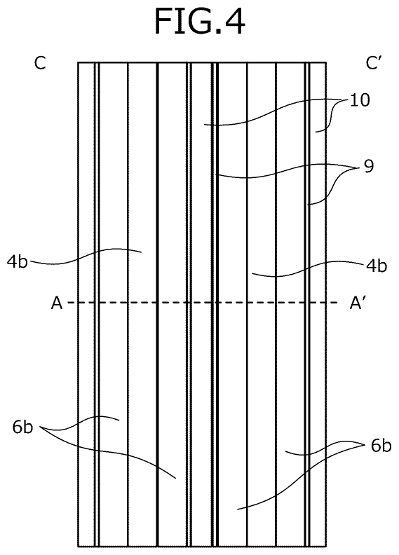

A semiconductor device according to the present invention is configured using a wide band gap semiconductor. In a first embodiment, a silicon carbide semiconductor device fabricated (manufactured) using, for example, silicon carbide (SiC) as a wide band gap semiconductor, is described taking a MOSFET as an example. FIG. 1 is a cross-sectional view of a structure of an active region a silicon carbide semiconductor device according to the first embodiment, along cutting line A-A′ in FIG. 3. FIG. 2 is a cross-sectional view depicting the structure of a termination structure region of the silicon carbide semiconductor device according to the first embodiment. FIG. 3 is a plan view of the structure of the silicon carbide semiconductor device according to the first embodiment, along cutting line B-B′ in FIG. 1. FIG. 4 is a plan view of the structure of the silicon carbide semiconductor device according to the first embodiment, along cutting line C-C′ in FIG. 1. FIGS. 1 to 4 depict an example of a trench-type MOSFET 50.

As depicted in FIG. 1, in the silicon carbide semiconductor device according to the first embodiment, at a first main surface (front surface), for example, a (0001)-plane (Si-face) of an n⁺-type silicon carbide substrate (silicon carbide semiconductor substrate of a first conductivity type) 1, an n⁻-type silicon carbide drift layer (first semiconductor layer of the first conductivity type) 2 is deposited.

The n⁺-type silicon carbide substrate 1 is a single crystal silicon carbide substrate. The n⁻-type silicon carbide drift layer 2 is formed by epitaxy and has a doping concentration lower than a doping concentration of the n⁺-type silicon carbide substrate 1. At a first surface of the n⁻-type silicon carbide drift layer 2, opposite to a second surface thereof facing the n⁺-type silicon carbide substrate 1, an n-type high-concentration region 6 may be provided. The n-type high-concentration region 6 is a high-concentration n-type layer with a doping concentration lower than the doping concentration of the n⁺-type silicon carbide substrate 1 but higher than the doping concentration of the n⁻-type silicon carbide drift layer 2. The n-type high-concentration region 6 may have a same carrier concentration as a carrier concentration of the n⁻-type silicon carbide drift layer 2. When the carrier concentration is the same, this region does not have a high concentration and thus, has a same carrier concentration as the carrier concentration of the n⁻-type silicon carbide drift layer 2 as a JFET1 region and a JFET2 region.

At a first surface of the n-type high-concentration region 6, opposite to a second surface thereof facing the n⁺-type silicon carbide substrate 1, a p-type base layer (second semiconductor layer of a second conductivity type) 3 is provided. Hereinafter, the n⁺-type silicon carbide substrate 1, the n⁻-type silicon carbide drift layer 2, and the p-type base layer 3 combined are assumed as a stacked silicon carbide semiconductor substrate.

At a second main surface (back surface, i.e., a back surface of the stacked silicon carbide semiconductor substrate) of the n⁺-type silicon carbide substrate 1, a drain electrode constituting a back electrode 13 is provided.

In the stacked silicon carbide semiconductor substrate, at the first main surface thereof (surface having the p-type base layer 3), a trench structure is formed. In particular, trenches 16 penetrate through the p-type base layer 3 from a first surface (surface facing the first main surface of the stacked silicon carbide semiconductor substrate) of the p-type base layer 3, opposite to a second surface of the p-type base layer 3 facing the n⁺-type silicon carbide substrate 1, the trenches 16 reaching the n-type high-concentration region 6. Further, the trenches 16 are provided in a stripe-like pattern. Along an inner wall of each of the trenches 16, a gate insulating film is formed along a bottom and sidewalls of the trench 16, and on the gate insulating film in the trench 16, a gate electrode 10 is formed. The gate insulating film insulates the gate electrode 10 from the n-type high-concentration region 6 and the p-type base layer 3. A portion of the gate electrode 10 may protrude from a top (side facing a later-described source electrode pad 14) of the trench 16, in a direction toward the source electrode pad 14.

At the first surface (surface facing the first main surface of the stacked silicon carbide semiconductor substrate) of the n-type high-concentration region 6, first p⁺-type base regions (first base region of the second conductivity type) 4 are selectively provided. The first p⁺-type base regions 4 are provided at least in the n-type high-concentration region 6, at the first surface of the n-type high-concentration region 6. The first p⁺-type base regions 4 are apart from the trenches 16 and reach deep positions closer to the back electrode 13 than are the bottoms of the trenches 16. The first p⁺-type base regions 4 are configured by first p⁺-type regions 4a and second p⁺-type regions 4b provided at surfaces of the first p⁺-type regions 4a, the first p⁺-type regions 4a each having a same thickness as a thickness of second p⁺-type regions 5 depicted below.

The second p⁺-type base regions (second base regions of the second conductivity type) 5 are provided at positions, respectively, facing the bottoms of the trenches 16 in a depth direction of the device. A width of each of the second p⁺-type base regions 5 is a same as a width of each of the trenches 16 or wider. The bottoms of the trenches 16 may reach the second p⁺-type base regions 5 or may be positioned in the n-type high-concentration region 6 so as to be between the p-type base layer 3 and the second p⁺-type base regions 5. The first p⁺-type base regions 4 and the second p⁺-type base regions 5 are doped with, for example, aluminum (Al).

Portions of each of the first p⁺-type base regions 4 may extend toward the trenches 16 so as to be connected to the second p⁺-type base regions 5. The first p⁺-type regions 4a of the first p⁺-type base regions 4 depicted in FIG. 1 have portions closer to the back electrode 13 than are the bottoms of the trenches 16, the portions extending toward the trenches 16 and as depicted in FIG. 3, the first p⁺-type regions 4a and the second p⁺-type base regions 5 are connected to one another. Further, portions of the second p⁺-type regions 4b depicted in FIG. 4 may extend toward the trenches 16 and be connected to the second p⁺-type base regions 5. FIG. 1 depicts an area where the first p⁺-type base regions 4 and the second p⁺-type base regions 5 are disposed apart from one another.

Further, as depicted in FIG. 2, the trench-type MOSFET 50 has an active region 30 through which current flows in an on-state and in which the device structure is formed, a termination structure region 32 surrounding a periphery of the active region 30 and sustaining a breakdown voltage, and a connecting region 31 between the active region 30 and the termination structure region 32.

In the termination structure region 32, the p-type base layer 3 and the n-type high-concentration region 6 are removed, the n-type silicon carbide drift layer 2 is exposed, and on the n⁻-type silicon carbide drift layer 2, a voltage withstand structure such as a junction termination extension (JTE) is provided.

The JTE structure has p-type regions disposed in descending order of doping concentration in a direction from a center (center of the n⁺-type silicon carbide substrate 1) to a substrate end (end of the n⁺-type silicon carbide substrate 1). The p-type regions (in FIG. 2, a JTE1 region 33, a JTE2 region 34) of different doping concentrations are disposed in a substantially rectangular shape surrounding the periphery of the active region 30 in a plan view of the device. Outside the JTE structure, a high-concentration n-type region 24 constituting a channel stopper is disposed. At surfaces of the JTE structure and the n-type region 24, an interlayer insulating film 11 is provided, and at the surface of the trench-type MOSFET 50, a protective film 25 containing, for example, a polyimide is provided.

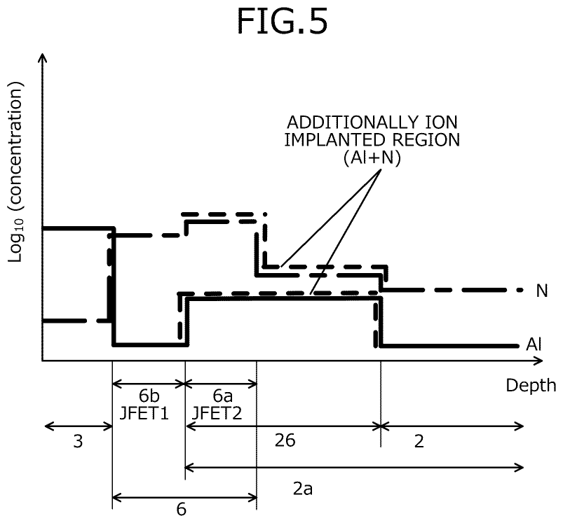

Here, FIG. 5 is a graph showing a dopant depth profile of the silicon carbide semiconductor device according to the first embodiment. In FIG. 5, a horizontal axis indicates depth from the p-type base layer 3 to the n⁻-type silicon carbide drift layer 2 in a direction indicated by arrow A in FIG. 1 while a vertical axis indicates doping concentrations of aluminum (Al) and nitrogen (N). Here, a JFET1 region 21 is a portion, an n-type high-concentration region 6b, between a sidewall of any one the trenches 16 and an adjacent one of the second p⁺-type regions 4b while a JFET2 region 22 is a portion, an n-type high-concentration region 6a, between any one of the second p⁺-type base regions 5 and an adjacent one of the first p⁺-type regions 4a (refer to FIG. 1) in a direction parallel to the first main surface of the stacked silicon carbide semiconductor substrate 1. In FIG. 5, the vertical axis is in logarithmic scale, which means that in the p-type base layer 3, the concentration of N is lower than the detection limit. This further means that in the n-type high-concentration region 6b and the n⁻-type silicon carbide drift layer 2, the concentration of Al is lower than the detection limit of secondary ion mass spectrometry (5×10¹³/cm³).

In the first embodiment, an additionally ion-implanted region 26 in which Al is ion-implanted by a high acceleration energy is provided in the JFET2 regions 22 and a surface layer of the n⁻-type silicon carbide drift layer 2. As for other descriptive names, the additionally ion-implanted region 26 may be called a co-doped region or a reduced carrier lifetime region. The Al doping concentration of the additionally ion-implanted region 26 is at least 1×10¹⁵/cm³ and preferably, is not more than 6×10¹⁶/cm³, which is the N doping concentration of the n⁻-type silicon carbide drift layer 2. When doping concentrations of the additionally ion-implanted region 26 are such that a combined doping concentration of N and Al exceeds 1.3×10¹⁷/cm³, resistance increases. Therefore, preferably, the combined doping concentration of N and Al may have an upper limit of 1×10¹⁷/cm³. In an instance of a breakdown voltage class of 1.2 kV, preferably, an upper limit of the N doping concentration may be 7×10¹⁶/cm³ while an upper limit of the Al doping concentration may be 6×10¹⁶/cm³ so that a difference of the N doping concentration less the Al doping concentration is, for example, about 1×10¹⁶/cm³. Preferably, a thickness of the additionally ion-implanted region 26 may be in a range of 0.1 μm to 4 μm. Setting the thickness to be at least 0.1 μm has an effect of reducing the carrier lifetime and an upper limit of 4 μm is a practical formation thickness by ion implantation equipment. The additionally ion-implanted region 26 is ion-implanted with Al, whereby crystal defects are formed. The additionally ion-implanted region 26 is ion-implanted with Al, whereby the carrier lifetime is reduced. Due to this reduction of the carrier lifetime, carriers (electrons, holes) are less likely to accumulate in the n⁻-type silicon carbide drift layer 2 when a body diode of the MOSFET conducts in a forward direction and a phenomenon of degraded conduction may be suppressed. Further, while accumulated carriers are discharged when high voltage is applied to the MOSFET during switching, loss equivalent to current×applied voltage occurs during discharge. As a result, when the accumulated carriers decrease, the discharged current also decreases, whereby switching loss decreases. In the additionally ion-implanted region 26, to compensate for the concentration change due to the ion-implantation of Al, preferably ion-implantation of N is again performed to increase the doping concentration of N. Therefore, the additionally ion-implanted region 26 is adjusted so that the doping concentration of N is higher than the doping concentration of the n⁻-type silicon carbide drift layer 2 by an amount equivalent to the doping concentration of Al.

Table 1 shows doping concentrations and thicknesses of regions in FIG. 1.

TABLE 1

| | TYPICAL VALUE | | |
|---|---|---|---|
| | DOPANT | DOPING | |
| REGION | ION | CONCENTRATION | OPTIMAL RANGE |
| p-TYPE BASE LAYER 3 | Al | 1.3 × 10¹⁷/cm³ | 1 × 10¹⁶/cm³-2 × 10¹⁷/cm³ |
| | | | THICKNESS: 0.1 μm-0.5 μm |
| JFET1 REGION 21 | N | 1 × 10¹⁷/cm³ | 1 × 10¹⁶/cm³-2 × 10¹⁷/cm³ |
| SECOND n-TYPE | | | THICKNESS: 0.1 μm-0.5 μm |
| REGION 6b | | | |
| JFET2 REGION 22 | N | N—Al ≤ 1 × 10¹⁷/cm³ | N: 1 × 10¹⁶/cm³-2 × 10¹⁷/cm³ |
| FIRST n-TYPE | Al | N > Al ≥ 1 × 10¹⁵/cm³ | Al: 1 × 10¹⁵/cm³-6 × 10¹⁶/cm³ |
| REGION 6a | | | THICKNESS: 0.1 μm-0.5 μm |
| ADDITIONALLY ION- | N | N—Al ≥ n⁻-TYPE DRIFT LAYER 2 | Al: 1 × 10¹⁵/cm³-6 × 10¹⁶/cm³ |
| IMPLANTED | Al | N > Al ≥ 1 × 10¹⁵/cm³ | THICKNESS: 0.1 μm-4 μm |
| REGION 26 | | | |
| n⁻-TYPE | N | 1 × 10¹⁶/cm³ | 1 × 10¹⁵/cm³-2 × 10¹⁶/cm³ |
| DRIFT LAYER 2 | | | THICKNESS: 10 μm-60 μm |
| SECOND p⁺-TYPE | Al | 3 × 10¹⁸/cm³ | 1 × 10¹⁸/cm³-1 × 10¹⁹/cm³ |
| REGION 4b | | | THICKNESS: 0.1 μm-4 μm |
| FIRST p⁺-TYPE | Al | 3 × 10¹⁸/cm³ | 1 × 10¹⁸/cm³-1 × 10¹⁹/cm³ |
| REGION 4a | | | THICKNESS: 0.1 μm-4 μm |

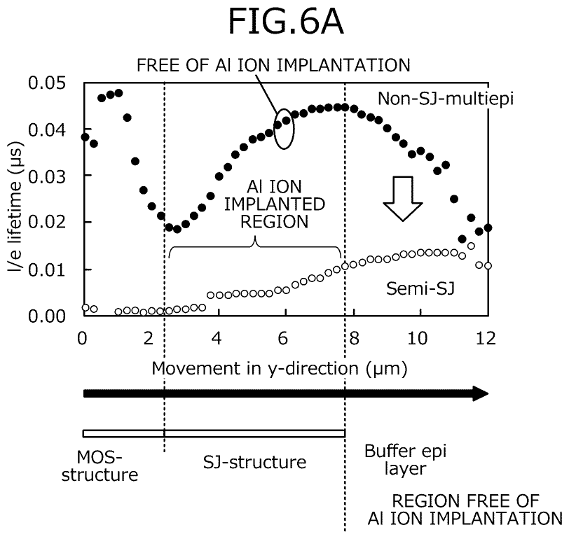

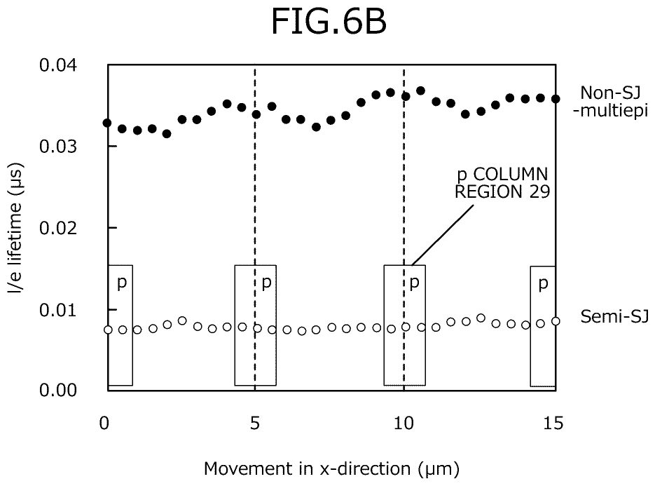

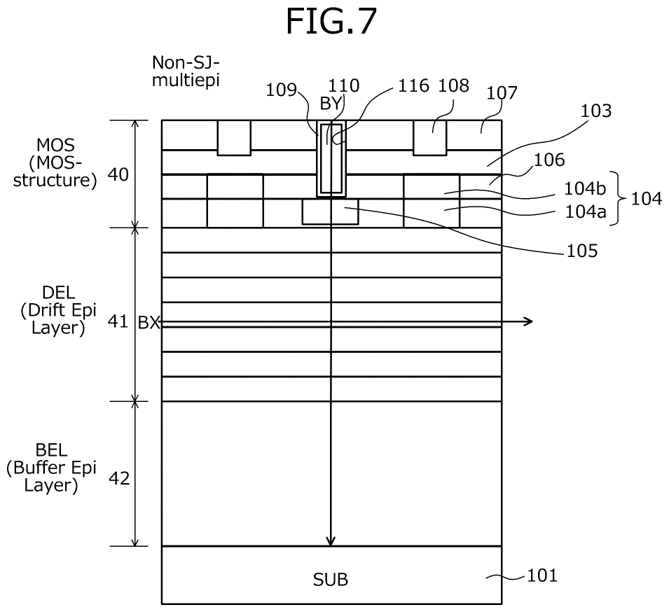

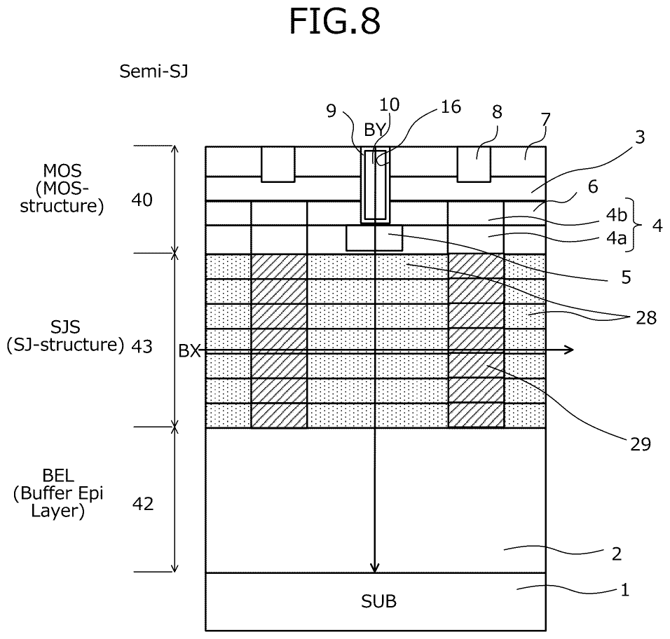

Here, experimental results from which knowledge was obtained pertaining to the embodiment, which uses a region in which the carrier lifetime is reduced by ion implantation, are described with reference to FIGS. 6A to 10. Hereinafter, carrier lifetime may be referred to as simply “lifetime”. FIGS. 6A and 6B are graphs showing, by comparison of a non-SJ-multiepi device in FIG. 7 and a semi-SJ device in FIG. 8 (Al ion-implantation being performed selectively in a SJ structure of the semi-SJ device), decreases in the lifetime due to Al ion-implantation in the silicon carbide semiconductor device. More specifically, as described hereinafter, crystal defects occurring as a result of the Al ion-implantation cause decreases in the lifetime. In FIGS. 6A and 6B, a vertical axis indicates the lifetime in units of μs. In FIG. 6A, a horizontal axis indicates depth in units of μm from any one of the trenches 116 in FIGS. 7 and 8, in a direction indicated by arrow BY, along an n-column. Further, in FIG. 6B, a horizontal axis indicates horizontal position in units of μm, in a direction indicated by arrow BX in FIGS. 7 and 8, along a cross-section of p-columns and n-columns. FIG. 6B corresponds to distribution of the lifetime in a horizontal direction, at about 5.7 μm on the horizontal axis in FIG. 6A. FIG. 6B also schematically depicts p-column regions 29 of the SJ structure, inserted having a repeat pitch of 5 μm and a width of 1.5 μm. Resolution during measurement is wider than the width of each of the trenches 116 and thus, the lifetime is evaluated from an attenuation time constant until the excited carrier density at a point of arrow BY of the trenches 116 becomes 1/e. The lifetime is obtained by a microscopic free carrier absorption method after a cross-section of the semiconductor device is obtained by polishing. A pulsed laser with a wavelength of 355 nm is used as excitation light and the injection photon density is on an order of 10¹⁷/cm². Further, a CW laser with a wavelength of 405 nm or 637 nm is used for the probe light. Details of the microscopic free carrier absorption method are described by K. Nagaya et al, “Observation of carrier lifetime distribution in 4H—SiC thick epilayers using microscopic time-resolved free carrier absorption system”, Journal of Applied Physics, 128, (2020), pp. 10570 and Fukui, Takuya, et al, “Carrier Lifetime Distribution in 4H—SiC SJ-UMOSFET”, The 67th JSAP Spring Meeting 2020 (Mar. 12 to 15, 2020), Proceedings 14a-A410-9. In the present specification, the term “carrier lifetime” (lifetime) typically means the carrier lifetime obtained by the microscopic free carrier absorption method.

In FIG. 6A, the lifetime of the SJ structure (SJ-structure, range of about 2.4 μm to 7.8 μm of horizontal axis) of a semi-SJ is in a range of 0.0001 μs to 0.01 μs and is not more than 0.01 μs (10 ns). In contrast, in a corresponding range of the horizontal axis, the lifetime of the non-SJ-multiepi is in a range of about 0.025 μs to 0.045 μs. The lifetime at 2.4 μm of the horizontal axis is 0.02 μs for the non-SJ-multiepi while the lifetime is 0.001 μs for the semi-SJ, which is less than 1/10. The lifetime at 7.8 μm of the horizontal axis is 0.045 μs for the non-SJ-multiepi while the lifetime is 0.01 μs for the semi-SJ, which is less than ¼. Thus, it is understood that at least the semi-SJ has an effect of reducing the lifetime by at least ¼. As depicted in FIG. 6B, the lifetime of the semi-SJ is about the same in the p-columns ion-implanted with Al and in the n-columns free of Al ion-implantation, and similar to FIG. 6A, is lower than the lifetime of the non-SJ-multiepi.

FIG. 7 is a cross-sectional view depicting a structure of the multiepi of the non-SJ-multiepi, which is a trench MOS structure in which no superjunction structure is formed in the drift layer. FIG. 8 is a cross-sectional view depicting, in addition to the structure in FIG. 7, the semi-SJ, which is a trench MOS structure in which Al ion-implantation is performed in portions of the drift layer. In FIG. 8, Al is ion-implanted in a lattice-like pattern in the drift layer, thereby forming the superjunction structure (SJ structure). In FIG. 7, a buffer layer 42 at the surface facing the n⁺-type silicon carbide substrate 101, and a drift epi layer 41 and a MOS structure 40 of the multiepi are provided. The buffer layer 42 and the drift epi layer 41 correspond to the n⁻-type silicon carbide drift layer 2. The drift epi layer 41 in FIG. 7 is assumed to be an n-type multiepi structure free of Al ion-implantation for comparison to the semi-SJ in later-described FIG. 8. The semi-SJ in FIG. 8 is assumed to be a SJ structure 43 having a pn parallel structure constituted by n-column regions 28 and the p-column regions 29, instead of the drift epi layer 41 in FIG. 7. The SJ structure 43 is formed by multiepi in which a process of forming an n-type epitaxial layer constituting the n-column regions 28 and selectively performing Al ion-implantation at positions forming the p-column regions 29 is performed multiple times. The acceleration energy when the ion implantation is performed is a maximum of 700 keV. To more effectively reduce the lifetime, the implantation may be performed by a higher acceleration energy (maximum: 8MeV).

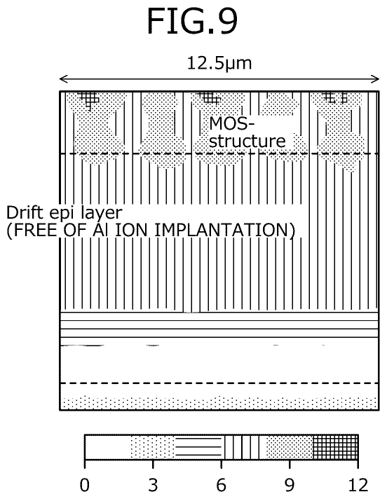

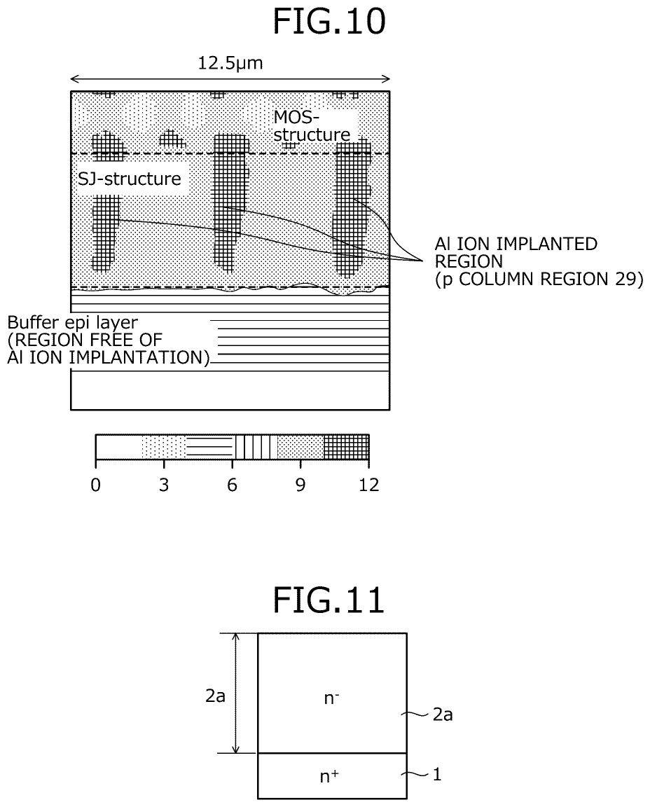

FIG. 9 is a diagram depicting L1 line emission intensity of the silicon carbide semiconductor device in FIG. 7. FIG. 10 is a diagram depicting L1 line emission intensity of the silicon carbide semiconductor device in FIG. 8. Here, the L1 line is emission with a wavelength of 425 nm (422-428 nm intensity accumulation) and is reported to be emission caused by the Si—C anti-site defect of SiC. While FIGS. 9 and 10 map emission intensity 1 to 12 of an arbitrary scale, classified into 6 levels, it is understood that the larger is the numerical value of the emission intensity, the greater the number of defects a region has.

As depicted in FIGS. 6A, 6B, and 10, regions in which Al ion-implantation is performed are formed in the drift layer, whereby the lifetime is reduced not only in the Al ion-implanted regions but in a broader region such as in the n⁻-type silicon carbide drift layer 2 and the n-column regions 28 in a vicinity of the Al ion-implanted regions. The lifetime is thought to decrease due to the expansion of implantation defects. The experimental results in FIG. 6B support this assumption. Based on the findings obtained from the experiment in FIGS. 6A to 10, the additionally ion-implanted region 26 shown in FIG. 1 is introduced.

Here, description of the device structure depicted in FIG. 1 continues. It is known that the number of defects increases not only according to the dose amount but also in instances of high acceleration energy. Therefore, in the first embodiment, Al is deeply implanted in the JFET2 regions 22 by a high acceleration energy (for example, in a range of 700 keV to 8 MeV), whereby more defects are formed than conventionally and the defects expand to the n-type silicon carbide drift layer 2.

Further, even when Al is implanted so as to exhibit a box profile, the number of implantation stages is finite and a completely constant concentration is not achieved, whereby the profile exhibits fluctuations in the concentration. When the implanted Al concentration is too high, fluctuations in the concentration become large and compensation of the concentration becomes difficult and thus, the implanted Al concentration is set to be not more than the N concentration of the n⁻-type silicon carbide drift layer 2, which is a region to be implanted. Further, when the Al concentration is too low, even when ion implantation is performed by a high acceleration energy, the number of defects decreases and the effect is poor. Therefore, preferably, the Al concentration may be 1×10¹⁵/cm³ or greater.

The p-type base layer 3 is in contact with the first p⁺-type base regions 4. In the p-type base layer 3, n⁺-type source regions (first semiconductor regions of the first conductivity type) 7 are provided at the first main surface of the stacked silicon carbide semiconductor substrate. Further, p⁺⁺-type contact regions 8 may be selectively provided. In this instance, the n⁺-type source regions 7 and the p⁺⁺-type contact regions 8 are in contact with one another.

In the n⁻-type silicon carbide drift layer 2, at the first surface thereof, between the first p⁺-type base regions 4 and the second p⁺-type base regions 5, and between the p-type base layer 3 and the second p⁺-type base regions 5, the n-type high-concentration region 6 may be provided; the n-type high-concentration region 6 being formed to a position deeper than are positions of the first p⁺-type base regions 4 and the second p⁺-type base regions 5. Thus, a depth (thickness) of the n-type high-concentration region 6 is greater than a depth (thickness) of the first p⁺-type base regions 4 and a depth (thickness) of the second p⁺-type base regions 5. Further, the first p⁺-type base regions 4 and the second p⁺-type base regions 5 may be formed to a same depth position. Further, the n-type high-concentration region 6 may be provided so as to surround lower portions of the first p⁺-type base regions 4 and the second p⁺-type base regions 5, the lower portions facing the n⁺-type silicon carbide substrate 1.

In FIG. 1, while only two trench MOS structures are depicted, further MOS gate (metal-oxide-semiconductor insulated gate) structures with a trench structure may be disposed in parallel.

In an entire area of the first main surface of the stacked silicon carbide semiconductor substrate, the interlayer insulating film 11 is provided so as to cover the gate electrodes 10 embedded in the trenches 16. A source electrode (first electrode) 12 in contact with the n⁺-type source regions 7 and the p-type base layer 3 via contact holes opened in the interlayer insulating film 11 is provided. In an instance in which the p⁺⁺-type contact regions 8 are provided, the source electrode 12 is in contact with the n⁺-type source regions 7 and the p⁺⁺-type contact regions 8. The source electrode 12 is electrically insulated from the gate electrodes 10 by the interlayer insulating film 11. On the source electrode 12, the source electrode pad 14 is provided.

The device structure in FIG. 1, in a broad sense, may be regarded to be a structure in which the first semiconductor layer and the second semiconductor layer are provided on the n⁺-type silicon carbide substrate 1. Here, the first semiconductor layer includes the n⁻-type silicon carbide drift layer 2, the additionally ion-implanted region 26, second n-type regions 6b, the first p⁺-type base regions 4, and the second p⁺-type base regions 5. Further, second semiconductor layer includes the n⁺-type source regions 7, the p⁺⁺-type contact regions 8, and the p-type base layer 3.

Next, a method of manufacturing the silicon carbide semiconductor device according to the first embodiment is described. FIGS. 11, 12, 13, 14, 15, 16, 17, 18, and 19 are cross-sectional views schematically depicting states of the silicon carbide semiconductor device according to the first embodiment during manufacture.

First, as depicted in FIG. 11, the n⁺-type silicon carbide substrate 1 containing an n-type silicon carbide is prepared. Subsequently, on the first main surface of the n⁺-type silicon carbide substrate 1, a first n⁻-type silicon carbide epitaxial layer 2a containing silicon carbide is grown by epitaxy while an n-type dopant, for example, nitrogen atoms, is doped, the first n⁻-type silicon carbide epitaxial layer 2a having a doping concentration of, for example, about 1×10¹⁶/cm³ and a thickness of about 10 μm. A portion of the first n⁻-type silicon carbide epitaxial layer 2a constitutes the n⁻-type silicon carbide drift layer 2.

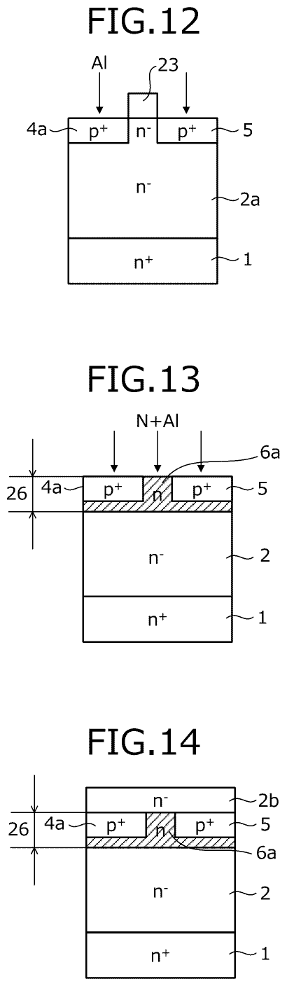

Next, on the surface of the first n-type silicon carbide epitaxial layer 2a, a mask 23 having predetermined openings is formed by photolithography using, for example, an oxide film. Subsequently, by ion implantation using the oxide film as the mask 23, a p-type dopant, for example, aluminum atoms, is ion-implanted. As a result, as depicted in FIG. 12, in the first n⁻-type silicon carbide epitaxial layer 2a, at the surface thereof, the first p⁺-type regions 4a and the second p⁺-type base regions 5 of a depth of, for example, about 0.5 μm are formed. The state up to here is depicted in FIG. 12.

Next, as depicted in FIG. 13, the mask 23 used during the ion implantation for forming the first p⁺-type regions 4a and the second p⁺-type base regions 5 is removed. Subsequently, a mask (not depicted) having predetermined openings is formed by photolithography using, for example, a resist or the like, the region 26, which is a portion of the active region and the connecting region depicted in FIGS. 1 and 2, is ion-implanted with an n-type dopant, for example, nitrogen atoms, and a p-type dopant, for example, aluminum atoms, by an ion implantation method. At this time, Al is implanted by a high acceleration energy (for example, at least 700 keV). As a result, as depicted in FIG. 13, on the first n⁻-type silicon carbide drift layer 2, between the first p⁺-type regions 4a and the second p⁺-type base regions 5, a first n-type region 6a containing a nitrogen doping concentration of about 1×10¹⁷/cm³ and an Al doping concentration of at least 1×10¹⁵/cm³ is formed to a depth 0.25 μm to 0.5 μm deeper than the depths of the first p⁺-type regions 4a and the second p⁺-type base regions 5. In an instance in which the n-type high-concentration region 6 is omitted, the N doping concentration of the first n-type region 6a is set to be about a same as the N doping concentration of the first n⁻-type silicon carbide drift layer 2. Here, the first n-type region 6a is formed so as to surround the lower portion (portion facing the n⁺-type silicon carbide substrate 1) of each of the first p⁺-type regions 4a and each of the second p⁺-type base regions 5.

Due to the ion implantation for forming the first n-type region 6a, the additionally ion-implanted region 26 is formed so as to overlap the first n-type region 6a. Portions of the first n-type region 6a between the first p⁺-type regions 4a and the second p⁺-type base regions 5 constitute the JFET2 regions 22. Due to this ion implantation, the additionally ion-implanted region 26 is formed in the termination structure region 32, up to the connecting region between the active region 30 and a JTE voltage withstand structure (the JTE1 region 33, the JTE2 region 34). The state up to here is depicted in FIG. 13. The sequence of the processes in FIGS. 12 and 13 may be interchanged.

Next, as depicted in FIG. 14, on the surface of the additionally ion-implanted region 26, a second n⁻-type silicon carbide epitaxial layer 2b is grown by epitaxy while an n-type dopant, for example, nitrogen atoms, is doped, the second n⁻-type silicon carbide epitaxial layer 2b having a thickness of, for example, about 0.5 μm. Conditions of the epitaxial growth for forming the second n⁻-type silicon carbide epitaxial layer 2b may be set so that, for example, the doping concentration of the second n⁻-type silicon carbide epitaxial layer 2b is about 8×10¹⁵/cm³. The state up to here is depicted in FIG. 14.

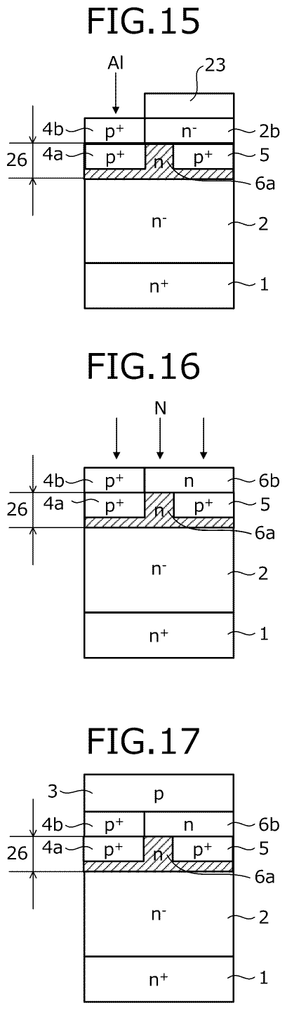

Next, as depicted in FIG. 15, on the surface of the second n⁻-type silicon carbide epitaxial layer 2b, the mask 23 having predetermined openings is formed by photolithography using, for example, an oxide film. Subsequently, by ion implantation using the oxide film as the mask 23, a p-type dopant, for example, aluminum atoms, is ion-implanted. As a result, as depicted in FIG. 15, in the second n⁻-type silicon carbide epitaxial layer 2b, at the surface thereof, the second p⁺-type regions 4b of a depth of, for example, about 0.5 μm, are formed, for example, so as to overlap upper portions of the first p⁺-type regions 4a, respectively. The second p⁺-type regions 4b and the first p⁺-type regions 4a combined constitute the first p⁺-type base regions 4. The state up to here is depicted in FIG. 15.

Next, the mask 23 used during the ion implantation for forming the second p⁺-type regions 4b is removed. Subsequently, as depicted in FIG. 16, an n-type dopant, for example, nitrogen atoms, is ion-implanted by an ion implantation method. As a result, as depicted in FIG. 16, in the second n⁻-type silicon carbide epitaxial layer 2b, at the surface thereof, the second n-type regions 6b, for example, of a depth of about 0.5 μm and a doping concentration of about 1×10¹⁷/cm³, are formed so as to be in contact with the first p⁺-type base regions 4, the second p³⁰ -type base regions 5, and the first n-type region 6a. The second n-type regions 6b and the first n-type region 6a combined constitute the n-type high-concentration region 6. The state up to here is depicted in FIG. 16. In an instance in which the n-type high-concentration region 6 is omitted, formation of the second n-type regions 6b is omitted.

Next, as depicted in FIG. 17, on the surfaces of the second p⁺-type regions 4b and the second n-type regions 6b, the p-type base layer 3 is grown by epitaxy while a p-type dopant, for example, aluminum atoms, is doped; the p-type base layer 3 has a thickness of, for example, about 1.3 μm. Conditions of the epitaxial growth for forming the p-type base layer 3 may be set so that, for example, the doping concentration is about 1.3×10¹⁷/cm³, which is lower than the doping concentration of the first p⁺-type base regions 4. By the processes up to here, the stacked silicon carbide semiconductor substrate in which the n⁻-type silicon carbide drift layer 2 and the p-type base layer 3 are stacked on the n⁺-type silicon carbide substrate 1 is formed. The state up to here is depicted in FIG. 17.

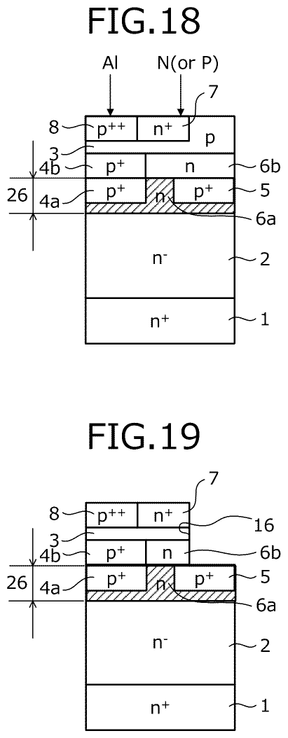

Next, as depicted in FIG. 18, on the surface of the p-type base layer 3, a non-depicted mask having predetermined openings is formed by photolithography using, for example, an oxide film. Subsequently, by an ion implantation method using the oxide film as a mask, an n-type dopant, for example, N or phosphorus (P) is ion-implanted. As a result, as depicted in FIG. 18, in the p-type base layer 3, at the surface thereof, the n⁺-type source regions 7 are formed.

Next, the mask used during the ion implantation for forming the n⁺-type source regions 7 is removed. Subsequently, on the exposed surface of the p-type base layer 3, a non-depicted mask having predetermined openings is formed by photolithography using, for example, an oxide film and a p-dopant, for example, aluminum, is ion-implanted at the surface of the p-type base layer 3, using the oxide film as a mask. As a result, in the p-type base layer 3, at the surface thereof, the p⁺⁺-type contact regions 8 are formed. The dose amount during the ion implantation for forming the p⁺⁺-type contact regions 8 may be set so that the doping concentration is, for example, higher than the doping concentration of the second p⁺-type base regions 5. The sequence in which the ion implantation for forming the n⁺-type source regions 7 and the ion implantation for forming the p⁺⁺-type contact regions 8 are performed may be interchanged. The state up to here is depicted in FIG. 18.

Subsequently, the p-type base layer 3 of an outer periphery of the chip is removed by dry etching, separating device elements and thereafter, in the outer periphery, for example, a voltage withstand structure (a JTE1 region 33, a JTE2 region 34) such as a junction termination extension (JTE) is formed by Al ion-implantation.

Next, a heat treatment (annealing) is performed, activating, for example, the first p⁺-type regions 4a, the second p⁺-type regions 4b, the n⁺-type source regions 7, and the p⁺⁺-type contact regions 8. A temperature of the heat treatment may be, for example, about 1700 degrees C. A period of the heat treatment may be, for example, about 2 minutes. Ion-implanted regions may be activated collectively by a single session of the heat treatment as described or may be activated by performing the heat treatment each time ion implantation is performed.

Next, as depicted in FIG. 19, on the surface of the p-type base layer 3 (i.e., the surfaces of the n⁺-type source regions 7 and the surfaces of the p⁺⁺-type contact regions 8), a non-depicted mask having predetermined openings is formed by photolithography using, for example, an oxide film. Subsequently, by for example, dry etching using the oxide film as a mask, the trenches 16 that penetrate through the n⁺-type source regions 7 and reach the n-type high-concentration region 6 are formed. The bottoms of the trenches 16 may reach the second p⁺-type base regions 5 or may be positioned in the n-type high-concentration region 6, between the p-type base layer 3 and the second p⁺-type base regions 5. Subsequently, the mask used to form the trenches 16 is removed. The state up to here is depicted in FIG. 19.

Next, a field oxide film (not depicted) is deposited on the surface of the outer periphery of the chip and thereafter, on the surfaces of the n⁺-type source regions 7, the surfaces of the p⁺⁺-type contact regions 8, and along the bottoms and sidewalls of the trenches 16, the gate insulating film is formed. The gate insulating film may be formed by thermal oxidation by a heat treatment of a temperature of about 1000 degrees C. under an oxygen atmosphere. Further, the gate insulating film may be formed by a deposition method by a chemical reaction such as that for a high temperature oxide (HTO).

Next, on the gate insulating film, a polycrystalline silicon layer doped with, for example, phosphorus atoms, is formed. The polycrystalline silicon layer is formed so as to be embedded in the trenches 16. The polycrystalline silicon layer is patterned and left in the trenches 16, thereby forming the gate electrodes 10. The gate electrodes 10 may partially protrude from tops (sides facing the source electrode pad 14) of the trenches 16, in a direction toward the source electrode pad 14.

Next, for example, a phosphate glass having a thickness of about 1 μm is deposited so as to cover the gate insulating film and the gate electrodes 10, thereby forming the interlayer insulating film 11. The interlayer insulating film 11 and the gate insulating film are patterned and selectively removed, thereby forming contact holes and exposing the n⁺-type source regions 7 and the p⁺⁺-type contact regions 8.

Next, for example, by a sputtering method, the source electrode 12 in contact with the n⁺-type source regions 7 and the p⁺⁺-type contact regions 8 is formed and at the second main surface of the n⁺-type silicon carbide substrate 1, the back electrode 13 is formed. Thereafter, a heat treatment (sintering) for forming an alloy layer is performed. Next, for example, by a sputtering method, for example, an aluminum film having a thickness of, for example, about 5 μm is formed so as to cover the source electrode 12 and the interlayer insulating film 11. Thereafter, the aluminum film is selectively removed and partially left so as to cover the entire device element active region, whereby the source electrode pad 14 and a gate electrode pad (not depicted) are formed.

Thereafter, as a surface passivation film, a polyimide is applied by, for example, spin coating, patterned by photolithography, and cured by a heat treatment. Next, at the surface of the back electrode 13, for example, by a vapor deposition method, titanium (Ti), nickel (Ni), and gold (Au) may be sequentially deposited. Thus, as described, the semiconductor device depicted in FIGS. 1 to 4 is completed.

As described, according to the first embodiment, Al is ion-implanted from the JFET2 regions to the n⁻-type silicon carbide drift layer with high acceleration energy. As a result, the lifetime of the n⁻-type silicon carbide drift layer decreases, switching loss may be reduced, and conduction degradation due to expansion of stacking faults may be suppressed.

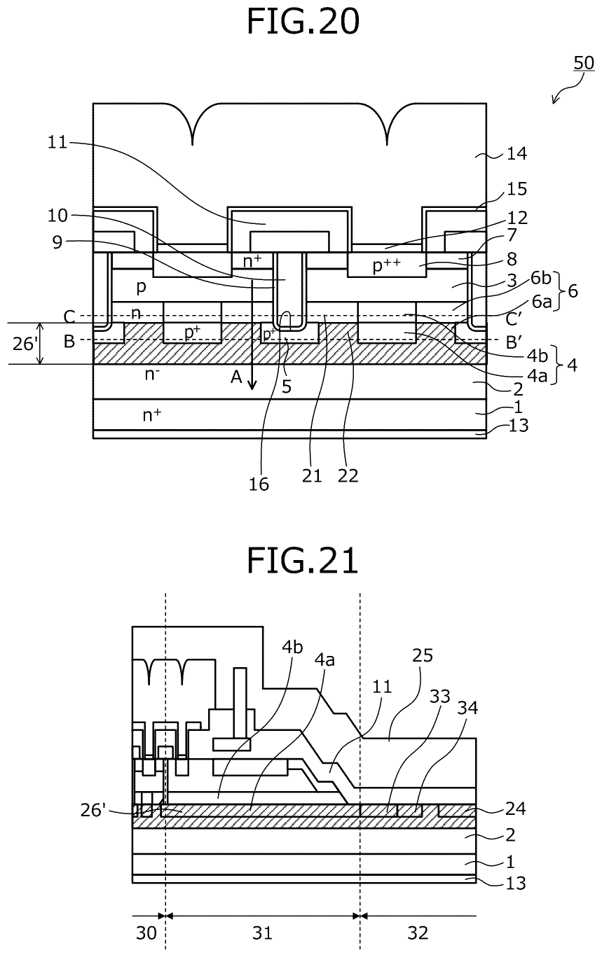

Next, a second embodiment is described with reference to FIGS. 20 to 24B. FIG. 20 is a cross-sectional view depicting a structure of an active region of a silicon carbide semiconductor device according to the second embodiment. FIG. 21 is a cross-sectional view depicting a structure of a termination structure region of the silicon carbide semiconductor device according to the second embodiment. A plan view along cutting line B-B′ in FIG. 20 is a same as that depicted in FIG. 3 while a plan view along cutting line C-C′ in FIG. 20 is a same as that depicted in FIG. 4 and thus, plan views of the silicon carbide semiconductor device according to the second embodiment along cutting lines B-B′ and C-C′ are omitted.

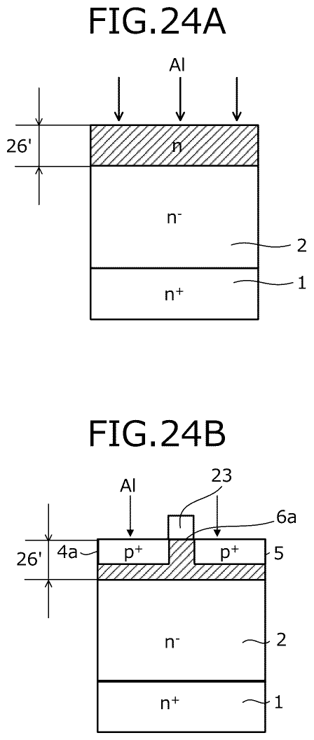

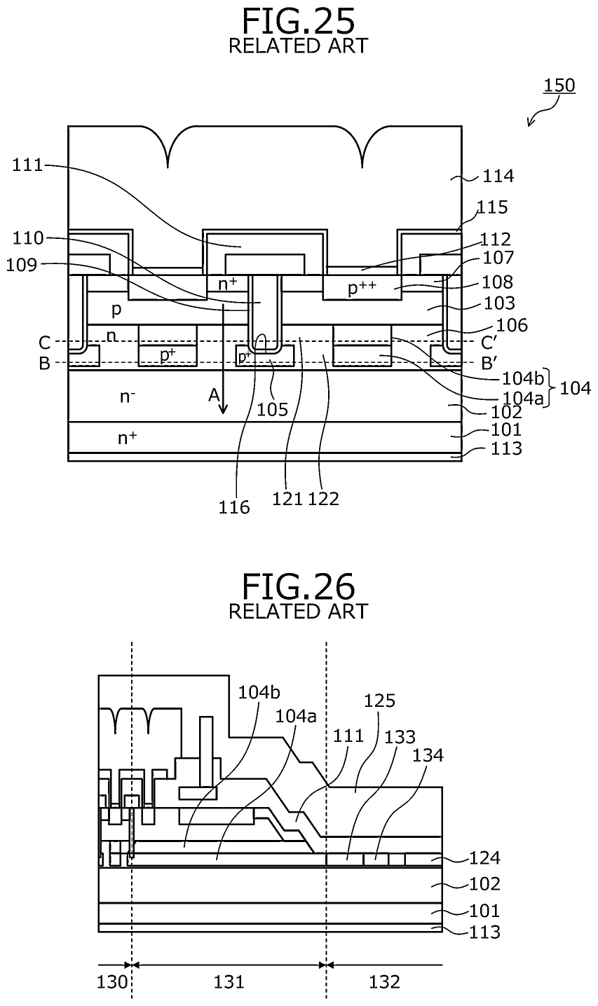

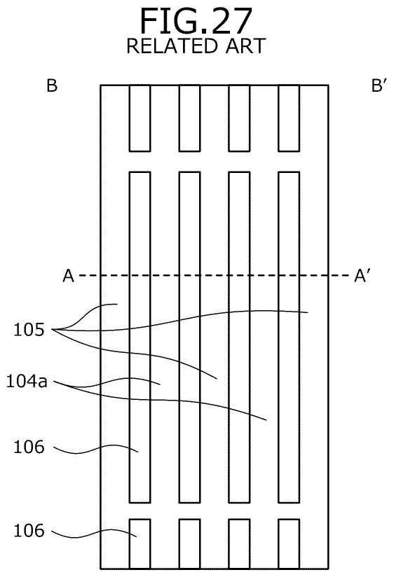

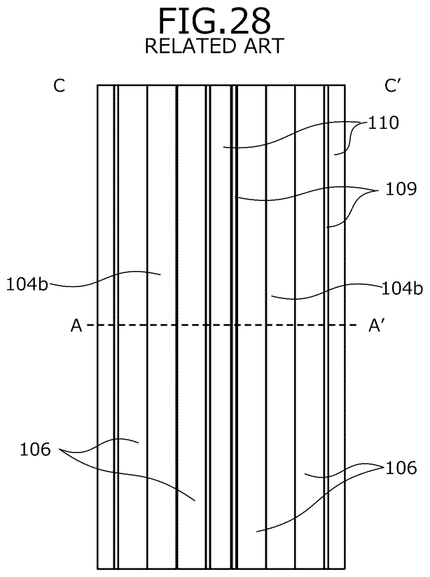

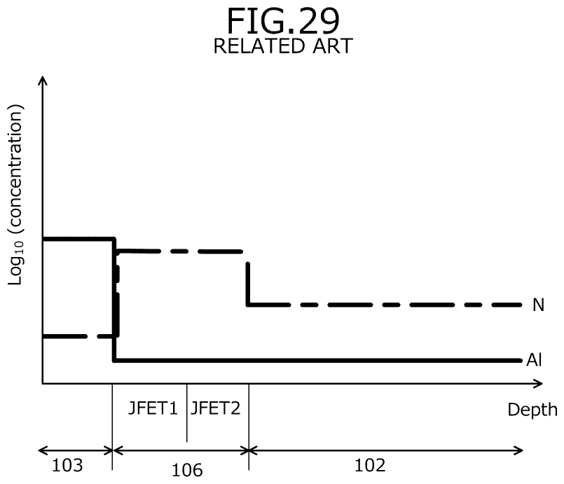

As depicted in FIG. 20, similar to the first embodiment, in the second embodiment, an additionally ion-implanted region 26′ ion-implanted with Al by a high acceleration energy is provided in the JFET2 regions 22 and the n⁻-type silicon carbide drift layer 2. In the second embodiment, the reference numeral of the additionally ion-implanted region is “26′”. This notation means that, as described hereinafter and depicted in FIGS. 23 to 24B, the formation procedure is different. FIG. 20 depicts a cross-section that is substantially a same as that of the first embodiment depicted in FIG. 1.

In the second embodiment, in FIGS. 23 to 24B, as described hereinafter, to compensate for concentration changes due to the ion-implantation of Al, at the surface of the n⁻-type silicon carbide drift layer 2, an additional n-type region (third semiconductor layer of the first conductivity type) 27 with a doping concentration higher than the doping concentration of the n⁻-type silicon carbide drift layer 2 is formed by epitaxy. The additional n-type region 27 is formed successively when the n⁻-type silicon carbide drift layer 2 is grown by epitaxy. Therefore, the additional n-type region 27 is provided not only in the active region 30 but also in the connecting region 31 and the termination structure region 32. In other words, in FIG. 21, the additionally ion-implanted region 26′ is formed in an entire area of the surface of the n⁻-type silicon carbide drift layer 2. On the other hand, in FIG. 2 of the first embodiment, the additionally ion-implanted region 26 differs in that the additionally ion-implanted region 26 is formed in the active region 30 and in a portion of the connecting region 31.

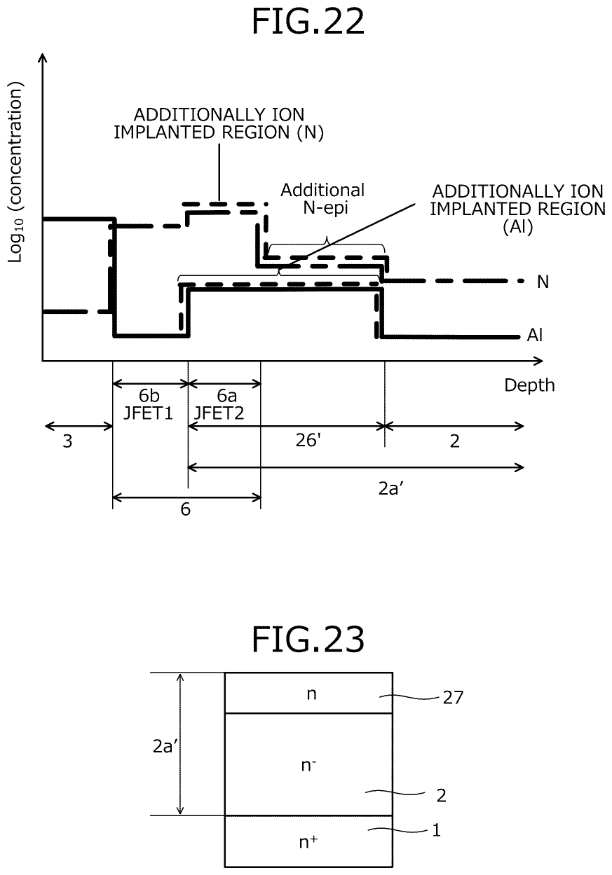

FIG. 22 is a graph showing a dopant depth profile of the silicon carbide semiconductor device according to the second embodiment. FIG. 22 is substantially a same as FIG. 5. In FIG. 22, a horizontal axis indicates depth from the p-type base layer 3 to the n⁻-type silicon carbide drift layer 2 in a direction indicated by arrow A in FIG. 20 while a vertical axis indicates doping concentrations of Al and N.

Next, a method of manufacturing the silicon carbide semiconductor device according to the second embodiment is described. FIGS. 23, 24A, and 24B are cross-sectional views schematically depicting states of the silicon carbide semiconductor device according to the second embodiment during manufacture. Here, only states different from states during manufacture according to the method of manufacturing the silicon carbide semiconductor device according to the first embodiment are depicted.

First, as depicted in FIG. 23, the n⁺-type silicon carbide substrate 1 containing an n-type silicon carbide is prepared. Subsequently, on the first main surface of the n⁺-type silicon carbide substrate 1, the first n⁻-type silicon carbide drift layer 2 containing silicon carbide is grown by epitaxy while an n-type dopant, for example, nitrogen atoms, is doped, the first n⁻-type silicon carbide drift layer 2 having a thickness of, for example, about 30 μm.

Further, the additional n-type region 27 containing silicon carbide is successively grown by epitaxy on the surface of the first n⁻-type silicon carbide drift layer 2 while an n-type dopant, for example, nitrogen atoms is doped, the additional n-type region 27 having a thickness of, for example, about 4 μm. The doping concentration of the additional n-type region 27 corresponds to the doping concentration of the n⁻-type silicon carbide drift layer 2 by the compensation of the concentrations of N and Al and thus, the thickness of the n⁻-type silicon carbide drift layer 2 may be reduced by an amount equivalent to the depth that the defect forming Al is implanted. Further, as for the Al implantation concentration, similar to the first embodiment, while the lower limit is the Al concentration of 1×10¹⁵/cm³ or more, the upper limit may be increased not more than the concentration of the additional n-type region 27. The state up to here is depicted in FIG. 23. The n⁻-type silicon carbide drift layer 2 and the additional n-type region 27 combined may be called a first silicon carbide epitaxial layer 2a′.

Next, as depicted in FIG. 24A, in an entire area of the surface of the additional n-type region 27, in other words, in an entire area of the surface of the wafer, a p-type dopant, for example, aluminum atoms, is ion-implanted by an ion implantation method. As a result, defects are formed in the additional n-type region 27. In an instance in which ion implantation is performed in a portion by an extremely high acceleration energy, a thick ion implantation mask has to be formed and this thick mask leads to increased manufacturing cost. In the second embodiment, Al is implanted in the entire surface of the wafer without an implantation mask and thus, the manufacturing cost is suppressed and the Al ion-implantation may be implemented by an ultrahigh acceleration energy of 1 MeV or greater. At this time, the implantation depth of the Al ions may be the same as the implantation depth of the additional n-type region 27. Thus, the additionally ion-implanted region 26′ is formed.

Subsequently, as depicted in FIG. 24B, at the surface of the additionally ion-implanted region 26′, the mask 23 is formed and Al is ion-implanted, thereby forming the first p⁺-type regions 4a and the second p⁺-type base regions 5. Thereafter, the process in FIG. 14 of the first embodiment and subsequent processes are performed, whereby the silicon carbide semiconductor device according to the second embodiment may be manufactured. In the second embodiment, the process of ion-implanting N in FIG. 13 of the first embodiment may be omitted. Instead of this process. the additional n-type region 27 depicted in FIG. 23 is formed, which is advantageous in that a series of epitaxial growth is performed successively, whereby cost and time may be reduced.

As described, according to the second embodiment, the additional n-type region is provided on the n⁻-type silicon carbide drift layer and Al is ion-implanted in the additional n-type region by a high acceleration energy. As a result, the lifetime of the n⁻-type silicon carbide drift layer is reduced, switching loss may be reduced, and conduction degradation due to expansion of stacking faults may be suppressed. Further, Al is implanted in the entire area of the surface of the wafer without an implantation mask and thus, manufacturing cost is suppressed and the Al ion-implantation may be implemented by an ultrahigh acceleration energy of 1 MeV of greater.

In the foregoing, the present invention may be variously modified within a range not departing from the spirit of the invention and in the described embodiments, for example, dimensions, doping concentrations, etc. of regions may be variously set according to necessary specifications. Further, in the present invention, the first conductivity type is assumed to be an n-type and the second conductivity type is assumed to be a p-type in the embodiments.

The silicon carbide semiconductor device and the method of manufacturing a silicon carbide semiconductor device according to the present invention achieve an effect in that conduction degradation due to switching loss and expansion of stacking faults may be suppressed.

As described, the silicon carbide semiconductor device and the method of manufacturing a silicon carbide semiconductor device according to the present invention is useful for power semiconductor devices used in power converting equipment such as inverters, power source devices of various industrial machines, inverters of electric cars, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A silicon carbide semiconductor device, comprising:
a silicon carbide semiconductor substrate of a first conductivity type, the silicon carbide semiconductor substrate having a first main surface and a second main surface opposite to each other;
a first semiconductor layer of the first conductivity type, provided at the first main surface of the silicon carbide semiconductor substrate, the first semiconductor layer having a doping concentration lower than a doping concentration of the silicon carbide semiconductor substrate, the first semiconductor layer having a first surface and a second surface opposite to each other, the second surface facing the silicon carbide semiconductor substrate;
a second semiconductor layer of a second conductivity type, provided at the first surface of the first semiconductor layer, the second semiconductor layer having a first surface and a second surface opposite to each other, the second surface facing the silicon carbide semiconductor substrate;
a first semiconductor region of the first conductivity type, selectively provided in the second semiconductor layer, at the first surface of the second semiconductor layer;
a trench penetrating through the second semiconductor layer and the first semiconductor region and reaching the first semiconductor layer;
a first base region of the second conductivity type, provided at the first surface of the first semiconductor layer;
a second base region of the second conductivity type, provided in the first semiconductor layer, at a position facing a bottom of the trench in a depth direction of the device;
a gate insulating film provided in the trench;
a gate electrode provided on the gate insulating film in the trench;
an interlayer insulating film provided on the gate electrode;
a first electrode in contact with the first semiconductor region and the second semiconductor layer;
a second electrode provided at the second main surface of the silicon carbide semiconductor substrate; and
a co-doped region provided in the first semiconductor layer, including a region between the first base region and second base region and a layer that is closer to the silicon carbide semiconductor substrate than are the first base region and the second base region, the co-doped region being doped with aluminum and nitrogen, wherein
the co-doped region has a carrier lifetime not more than 0.01 μs.

2. The silicon carbide semiconductor device according to claim 1, wherein
a doping concentration of the aluminum in the co-doped region is at least 1×10¹⁵/cm³ but not more than a doping concentration of the nitrogen of the first semiconductor layer of a region doped with the aluminum.

3. The silicon carbide semiconductor device according to claim 1, wherein
a doping concentration of the nitrogen of the co-doped region of the first semiconductor layer is higher than a doping concentration of a portion of the first semiconductor layer excluding the co-doped region, by an amount equivalent to a doping concentration of the aluminum.

4. A method of manufacturing a silicon carbide semiconductor device,
the silicon carbide semiconductor device having:
a silicon carbide semiconductor substrate of an n-type, having a first main surface and a second main surface opposite to each other;
a first semiconductor layer of the n-type, provided at the first main surface of the silicon carbide semiconductor substrate, the first semiconductor layer having a doping concentration lower than a doping concentration of the silicon carbide semiconductor substrate, the first semiconductor layer having a first surface and a second surface opposite to each other, the second surface facing the silicon carbide semiconductor substrate;
a second semiconductor layer of a p-type, provided at the first surface of the first semiconductor layer, the second semiconductor layer having a first surface and a second surface opposite to each other, the second surface facing the silicon carbide semiconductor substrate;
a first semiconductor region of the n-type, selectively provided in the second semiconductor layer, at the first surface of the second semiconductor layer;
a trench penetrating through the second semiconductor layer and the first semiconductor region and reaching the first semiconductor layer;
a first base region of the p-type, provided in the first semiconductor layer, at the first surface of the first semiconductor layer;
a second base region of the p-type, provided in the first semiconductor layer, at a position facing a bottom of the trench in a depth direction of the device;
a gate insulating film provided in the trench;
a gate electrode provided on the gate insulating film in the trench;
an interlayer insulating film provided on the gate electrode;
a first electrode in contact with the first semiconductor region and the second semiconductor layer;
a second electrode provided at the second main surface of the silicon carbide semiconductor substrate; and
a co-doped region provided in the first semiconductor layer, including a region between the first base region and second base region and a layer that is closer to the silicon carbide semiconductor substrate than are the first base region and the second base region, the co-doped region being doped with aluminum and nitrogen,
the method comprising:
growing the first semiconductor layer by epitaxy; and
ion-implanting aluminum in the first semiconductor layer by a predetermined acceleration energy to thereby form the co-doped region.

5. The method according to claim 4, wherein
the growing the first semiconductor layer includes growing, by epitaxy, a first layer doped with nitrogen of a first concentration, and
the ion-implanting the aluminum includes ion-implanting the aluminum at a predetermined depth from a surface of the first layer,
the method further comprising, before or after the ion-implanting the aluminum, ion-implanting nitrogen in the first semiconductor layer so that a concentration of the nitrogen of the co-doped layer becomes a second concentration higher than the first concentration.

6. The method according to claim 4, wherein
the growing the first semiconductor layer includes growing, by epitaxy, a first layer doped with nitrogen of a first concentration and on the first layer, growing, by the epitaxy, a second layer doped with the nitrogen of a second concentration higher than the first concentration of the first layer, and
the ion-implanting the aluminum includes ion-implanting the aluminum at a depth of the second layer.

7. The method according to claim 4, wherein
the aluminum is ion-implanted by an acceleration energy of 700 keV or greater but not more than 8 MeV.

8. The method according to claim 4, wherein
the ion-implanting of the aluminum in the co-doped region reduces a carrier lifetime of the co-doped region to be lower than before the ion-implanting of the aluminum.

9. The method according claim 4, wherein
in the co-doped region, a doping concentration of the aluminum is at least 1×10¹⁵/cm³ but not more than a doping concentration of the nitrogen.
